(19) United States
(12) Patent Application Publication
(10) Pub. No.: US 2016/0356871 A1
(43) Pub. Date: Dec. 8, 2016

(54) DETERMINING SUBSTANCE WEIGHTINGS USING MAGNETIC RESONANCE SIGNALS

(71) Applicant: David Grodzki, Erlangen (DE)

(72) Inventor: David Grodzki, Erlangen (DE)

(21) Appl. No.: 15/151,313

(22) Filed: May 10, 2016

(30) Foreign Application Priority Data
Jun. 3, 2015 (DE) 102015210292.0

(51) Int. Cl. G01R 33/50; G01R 33/30; G01R 33/54; G01R 33/385

(52) U.S. Cl. CPC G01R 33/50; G01R 33/385; G01R 33/307; G01R 33/546

(57) ABSTRACT

Disclosed herein are a method for the quantification of a volume element composition and a magnetic resonance device and computer program product for carrying out the method. The method for the quantification of a volume element composition of an object under examination using magnetic resonance signals, which are generated by the interaction of electromagnetic waves with at least one component of the volume element, includes providing of a plurality of signal evolutions including an evaluation signal evolution of the magnetic resonance signals and at least one database signal evolution. The signal evolutions are used to determine weighting factors for the at least one component of the volume element. Each signal evolution includes a plurality of corresponding evaluation points, where each evaluation point is assigned a signal value.

This application claims the benefit of DE 10 2015 210 292.0, filed on Jun. 3, 2015, which is hereby incorporated by reference in its entirety.

### TECHNICAL FIELD

The embodiments relate to a method for the quantification of a volume element composition of an object under examination using magnetic resonance signals and a magnetic resonance device and computer program product for carrying out the method.

### BACKGROUND

In clinical imaging, magnetic resonance imaging (MRI) may be used to generate images of objects under examination with a much higher soft tissue contrast than is the case with computed tomography (CT). While CT enables quantitative values, such as Hounsfield units, to be measured, MR imaging may only provide a qualitatively weighted image. To date, quantitative MRI imaging methods with which, for example, the relaxation times are measured have not established themselves since they are often too imprecise and/or too slow.

A new and very promising quantitative MR imaging method suitable for solving the problems described is the magnetic resonance fingerprinting (MRF) method. One possible MRF method is for example known from the publication Ma et al., Magnetic Resonance Fingerprinting, Nature 495 (2013) 187-192. In this method, pseudorandomized shapes of inter alia flip angle and/or RF pulse phase and/or repetition time TR and/or echo time TE and/or inversion time TI are used to generate a specific signal evolution, (e.g., a fingerprint), over a large number of images, for example 1000 to 5000, pixel-by-pixel and/or voxel-by-voxel. With the aid of a database, this fingerprint may be unequivocally assigned to a specific n-tuple of physical values, such as, for example, T1 time, T2 time, off resonance, and hence to a single substance, such as, for example, liquor, gray brain matter etc.

However, a volume element of the object under examination, which is represented by a pixel and/or a voxel, contains not just one single substance but a plurality of components.

### SUMMARY AND DESCRIPTION

The scope of the present invention is defined solely by the appended claims and is not affected to any degree by the statements within this summary. The present embodiments may obviate one or more of the drawbacks or limitations in the related art.

The embodiments are based on the object of quantifying a volume element composition of an object under examination in an advantageous way using magnetic resonance signals.

A method for the quantification of a volume element composition of an object under examination using magnetic resonance signals generated by the interaction of electromagnetic waves with at least one component of the volume element may include providing a plurality of signal evolutions including an evaluation signal evolution of the magnetic resonance signals and at least one database signal evolution. The signal evolutions are used to determine weighting factors for the at least one component of the volume element. At the same time, each signal evolution in each case includes a plurality of corresponding evaluation points that are in each case assigned a signal value.

The plurality of signal evolutions may be provided with the aid of a provisioning unit. The provisioning unit may include one or more data memories, for example, a hard disk on which the magnetic resonance signals are stored.

The weighting factors of a specific component advantageously in each case represent a measure for a portion of the corresponding component out of the total number of components comprised by the volume element of the object under examination. The portion of a component may for example relate to the weight and/or the amount of substance and/or the volume and/or the proton count of the component. The weighting factors may be determined with the aid of an evaluation unit. To determine the weighting factors, it is possible, for example, to retrieve the magnetic resonance signals from a hard disk and transfer them to the evaluation unit by a data transmission unit.

A signal evolution may be based on a pulse sequence with which signal values comprised by the signal evolution are determined. For the provision of the evaluation signal evolution, advantageously, in a preceding act, magnetic resonance signals are measured by a magnetic resonance device using the pulse sequence. The database signal evolutions may be determined and/or simulated and/or calculated using the pulse sequence, for example, in a calibration measurement.

Each signal evolution may include a plurality of signal values, for example, 1000 to 5000 signal values. The signal values are in particular dependent on two influencing variables: on the one hand, on the excitation and acquisition of any possible magnetic resonance signals caused by the pulse sequence, wherein, this influencing variable may not differ at corresponding evaluation points from signal evolution to signal evolution and, on the other, on the interaction of the irradiated electromagnetic waves with the at least one component of the volume element of the object under examination.

Consequently, in particular, the resultant signal values at corresponding evaluation points are identical as long as the volume element of the object under examination in which the magnetic resonance signal is generated is also identical, e.g., the same components.

In particular, however, in the case of signal evolutions including numerous, (e.g., more than 10 or more than 100 or more than 1000), signal values, advantageously not all but only a part of the signal values are evaluated for the determination of the weighting factors, e.g., only signal values at the respective plurality of evaluation points are used. This restriction of the input values to be processed enables the computing time and/or the calculation effort required for the quantification of the composition to be minimized. Hence, an operator of a magnetic resonance device, (e.g., a doctor), may be provided with the weighting factors determined quickly. Therefore, in a further act, the weighting factors determined are made available to an operator.

The plurality of corresponding evaluation points corresponds from signal evolution to signal evolution, e.g., the signal values of different signal evolutions belonging to a corresponding evaluation point may result from the same recording parameters and/or simulation parameters. Therefore, corresponding evaluation points may be based on the same type of excitation and acquisition of any possible magnetic resonance signals, wherein the excitation and acquisition of possible magnetic resonance signals may be measured experimentally, (e.g., by a magnetic resonance device), and/or theoretically simulated, in particular by a computer.

It is in particular possible for corresponding evaluation points of two signal evolutions to occur at different places within the signal evolutions. This may, for example, be due to the fact that the pulse sequences on which the two signal evolutions are based have identical segments arranged at different places within the pulse sequence.

However, for purposes of simplification, it is advisable to generate the signal evolutions, for example, a first and a second signal evolution, on the basis of the same pulse sequence in order to obtain corresponding evaluation points. This results in signal evolutions with in each case a first signal value, a second signal value, etc. Then, for example, the second signal value of the first signal evolution is assigned to a corresponding evaluation point of the first signal evolution. This evaluation point of the first signal evolution corresponds to an evaluation point of the second signal evolution assigned to the second signal value of the second signal evolution since the first and the second signal evolution result from the same pulse sequence.

The signal evolutions may be generated according to a magnetic resonance fingerprinting method since such methods are particularly suitable for quantitative measurements. For example, a pulse sequence on which the magnetic resonance fingerprinting method is based may have a section-by-section variation of at least one, at least two, or at least three of the following parameters from section to section: a flip angle, a phase of an RF pulse, a repetition time TR, an echo time TE, an inversion time TI, a scanning pattern. A variation of recording parameters of this kind permits a very free and flexible arrangement of the pseudorandom excitation sequence.

The volume element may be depicted by a voxel and/or pixel of an MR image. For example, it is possible to generate one or more MR images from any possible magnetic resonance signals measured in a preceding act. These MR images may include at least one voxel and/or pixel, which in each case depict a volume element.

Advantageously, an operator of a magnetic resonance device may be provided in a voxel- and/or pixel-dependent way with additional information relating to the quantified composition of the associated volume element. It is, for example, conceivable that moving a cursor onto a voxel and/or pixel of the MR image will cause the operator to be shown additional information on the components of the corresponding volume element. It is also conceivable for the operator to be shown composition maps of the object under examination visualizing, for example, a color-coordinated location-dependent concentration component.

One embodiment of the method provides that at least one total number of possible components is defined for the determination of the weighting factors. This limiting condition enables the determination of the weighting factors to be simplified. The number of components actually comprised by the volume element may also be greater or smaller than the a priori defined total number of possible components. Advantageously, the definition of the total number of possible components makes use of empirical values and/or other a priori information that are, for example, dependent on the location of the volume element under consideration within the object under examination. Depending upon the region of interest, it is possible to assume different tissue types thus enabling an advantageous limitation of the total number of possible components.

At least one postulated component may be defined for the determination of the weighting factors. In this case, advantageously each of the at least one postulated component is in each case assigned a database signal evolution. This limiting condition enables the determination of the weighting factors to be simplified. The at least one postulated component is advantageously one or more components, which may be comprised by the volume element under consideration of the object under examination. During the determination of weighting factors, it may be assumed that postulated components are present in the volume element under consideration, (e.g., a weighting factor, in particular greater than zero), is determined for each postulated component.

Advantageously, the definition of the postulated components uses empirical values and/or other a priori information, which are, for example, dependent on the position of the volume element under consideration within the object under examination. Depending upon the region of interest, it is possible to assume different tissue types thus enabling an advantageous limitation of postulated components. The number of postulated components defined may be smaller or equal to a possible total number of possible components defined.

One embodiment of the method provides that, for the determination of the weighting factors, a plurality of potential components is defined, wherein each of the plurality of potential components is in each case assigned a database signal evolution. At least one resultant component is determined from the plurality of potential components.

The at least one potential component may be one or more components that have an average probability of being comprised by the volume element under consideration of an object under examination. It may be assumed during the determination of weighting factors that potential components are possibly present in the volume element under consideration, e.g., unlike the postulated components, the potential components are only candidates as components of the volume element under consideration of the object under examination. Consequently, the probability of being comprised by the volume element under consideration of an object under examination for potential components may be lower than it is for postulated components.

Advantageously, the determination of the potential components is performed using empirical values and/or other a priori information, which are, for example, dependent on the position of the volume element under consideration within the object under examination. Depending upon the region of interest, it is possible to assume different tissue types thus enabling an advantageous limitation of potential components.

The potential components form a quantity of potential components. The at least one resultant component determined from among the quantity of potential components may have a higher probability of being comprised by the volume element under consideration of an object under examination than the other components from among the quantity of potential components. Therefore, during the determination of the at least one resultant component, advantageously a degree of probability is determined, which is used to determine the at least one resultant component.

It is furthermore suggested that a plurality of weighting factors is calculated for each of the potential components, wherein the at least one resultant component has a minimum deviation of the plurality of weighting factors.

For example, it is possible to calculate the plurality of weighting factors of a potential component in that a weighting factor is in each case calculated at a plurality of corresponding evaluation points and/or for a plurality of groups of corresponding evaluation points.

A deviation, for example, a standard deviation, and/or a variance, may be determined for the plurality of weighting factors of a potential component. Further statistical methods for the determination of the deviation are also conceivable. In particular, a standard deviation and/or variance may be assessed in relation to a mean value of the weighting factors. Therefore, the deviation determined advantageously represents a measure for the scatter of the weighting factors and in particular a degree of probability, which may be used to determine the at least one resultant component. For example, a low deviation of the weighting factors of a potential component may indicate a high probability of the potential component actually being comprised by the volume element of the object under examination.

As described above, the evaluation signal evolution, which may include a plurality of signal values, may be determined using a specific pulse sequence from spatially encoded magnetic resonance signals for at least one volume element of the object under examination. In each case, the evaluation signal evolution may be used to determine a weighting factor for the at least one component of the volume element, in particular for postulated and/or resultant components. From these determined weighting factors, it is possible to determine for each of said components, their portion in the totality of all components of the volume element of the object under examination. The portion missing from the totality of all components may be referred to as a residual portion.

It is suggested that a residual signal evolution be determined, which is used to determine at least one piece of component information by comparison with a plurality of database signal evolutions. In particular, the residual signal evolution may be determined by the subtraction of determined signal portions from the signal values of the evaluation signal evolution, e.g., a residual signal evolution may be determined for the residual portion in that the weighting factors for said components, e.g., for postulated and/or resultant components, are used to calculate signal portions the sum of which is subtracted from the signal values of the evaluation signal evolution in each case. One possibility for calculating the signal portions is to multiply the signal values of the database signal evolutions associated with said components with the determined portions of the components.

In other words, the residual component may be applied to a plurality of, in particular all, signal values of the evaluation signal evolution so that a residual signal evolution results therefrom.

From this residual signal evolution, according to a magnetic resonance fingerprinting method, it is in turn possible by a database comparison to determine at least one further component, e.g., at least one piece of component information.

The weighting factors may be determined using a mean value of provisional weighting factors. For example, for the respective components in each case, a plurality of provisional weighting factors is determined for which a mean value is formed. The mean value, may, for example, be an arithmetic and/or a geometric mean value. The formation of a mean value enables the accuracy of the weighting factors determined to be increased.

One embodiment of the method provides that for the determination of the weighting factors at least one, in particular linear, system of equations is created and solved, wherein each of the at least one system of equations includes a plurality of equations. Each equation of the plurality of equations may relate to one of the corresponding evaluation points.

The signal value of the evaluation signal evolution at the corresponding evaluation point and the signal values of database signal evolutions of any possible components, (e.g., postulated and/or potential components), at the corresponding evaluation point may be input quantities for an equation (e.g., S_{M}=g_{A}·S_{A}+g_{A}·S_{B}+g_{C}·S_{C}+ etc., wherein S_{M} is the signal value of the evaluation signal evolution at the corresponding evaluation point, S_{A} is the signal value of the database signal evolution of the component A at the corresponding evaluation point, S_{B} is the signal value of the database signal evolution of the component B at the corresponding evaluation point, S_{C} is the signal value of the database signal evolution of the component C at the corresponding evaluation point, g_{A} is the weighting factor of the component A, g_{B} is the weighting factor of the component B and g_{C} is the weighting factor of the component C). Systems of equations, (e.g., linear systems of equations), may be solved relatively easily with known methods so that the method may be applied quickly.

A plurality of systems of equations may be created and solved, wherein each system of the plurality of systems of equations relates to a different compilation of corresponding evaluation points. In particular, the compilation of evaluation points is compiled from successive shape positions and/or randomly chosen shape positions.

The plurality of solutions to the systems of equations resulting therefrom may, for example, be used to determine a plurality of provisional weighting factors. This increases the statistical base, which may be used to form a mean value of the weighting factors. The shape position may be understood to be the position of the signal value within the signal evolution.

The number of equations comprised by the at least one system of equations is only the maximum number required for an unequivocal solution of the system of equations, e.g., with N unknown variables, the system of equations contains N independent equations. In particular, the number of equations of one of the at least one system of equations is equal to a number of weighting factors to be determined. This enables the number of equations to be solved and hence also the computing time to be minimized.

Also suggested is a magnetic resonance device, which is configured to carry out a method as disclosed herein. The magnetic resonance device may include a provisioning unit in order to provide a plurality of signal evolutions. The provisioning unit may include one or more data storage units, for example a hard disk on which signal evolutions are stored. In addition, the magnetic resonance device may include a data transmission unit and an evaluation unit, wherein the data transmission unit is embodied to transfer signal evolutions to the evaluation unit. The evaluation unit may be designed to determine weighting factors on the basis of the signal evolutions transferred.

The advantages of the magnetic resonance device substantially correspond to the advantages of the method for the quantification of a volume element composition of an object under examination using magnetic resonance signals, which are explained above in detail. Possible features, advantages or alternative embodiments mentioned thereby may also be transferred to the other subject matter claimed and vice versa.

Also suggested is a computer program product, which includes a program and may be loaded directly into a memory of an evaluation unit of a magnetic resonance device, wherein when the program is executed in the system control unit of the magnetic resonance device, the computer program product is configured to carry out the method embodiments disclosed herein.

In this case, the computer program product may include software with a source code that still has to be compiled and linked or which only has to be interpreted or an executable software code which, for execution, only needs to be loaded into a system control unit of the magnetic resonance device. The computer program product enables the method to be carried out quickly, in an identical repeatable way and robustly. The computer program product is configured such that it is able to carry out the method acts by the system control unit. In this case, the system control unit in each case meets conditions such as, for example, possession of a corresponding working memory, a corresponding graphics card, or a corresponding logic unit so that the respective method acts may be carried out efficiently. The computer program product is, for example, stored on a computer-readable medium or on a network or server from where it may be loaded into a processor of the system control unit. Examples of computer-readable media are a DVD, a magnetic tape or a USB stick on which electronically readable control information, in particular software, is stored. Thus, the embodiments may also be based on the computer-readable medium.

### BRIEF DESCRIPTION OF THE DRAWINGS

Further advantages, features and details of the embodiments may be derived from the examples described below and with reference to the drawings. Corresponding parts are given the same reference characters in all the figures, which show:

FIG. 1 depicts a schematic representation of a volume element including a plurality of components.

FIG. 2 depicts a block diagram of a method according to an embodiment.

FIG. 3 depicts a block diagram of an expanded method according to an embodiment.

FIG. 4 depicts an example of signal values from three component-specific database signal evolutions.

FIG. 5 depicts an example of signal values from an evaluation signal evolution.

FIG. 6 depicts an example of signal values from a residual signal evolution.

FIG. 7 depicts a schematic representation of a magnetic resonance device, according to an embodiment.

### DETAILED DESCRIPTION

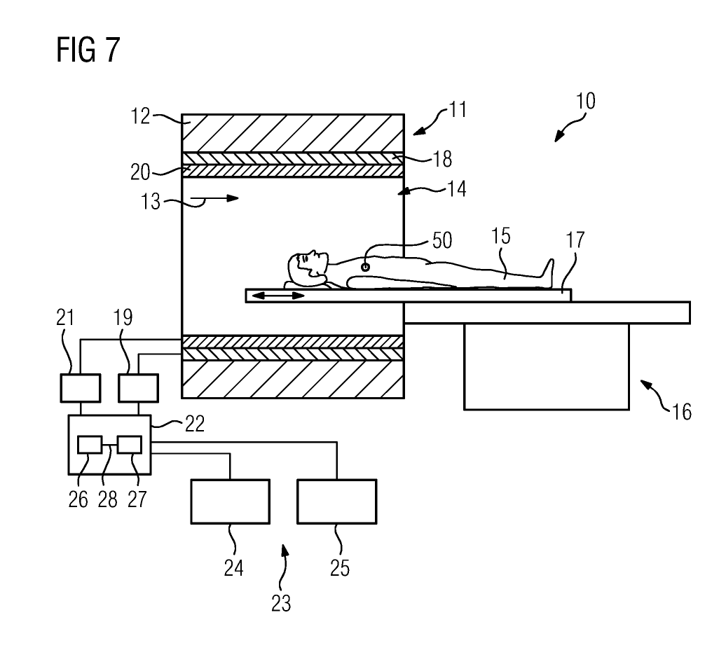

FIG. 7 is a schematic representation of a magnetic resonance device 10. The magnetic resonance device 10 includes a magnet unit 11 having a superconducting basic magnet 12 to generate a strong and in particular temporally constant basic magnetic field 13. The magnetic resonance device 10 also includes a patient receiving area 14 for receiving an object under examination 15, for example a patient. In the present exemplary embodiment, the patient receiving area 14 has a cylindrical shape and is surrounded in a circumferential direction by the magnet unit 11 in a cylindrical manner. However, in principle, an embodiment of the patient receiving area 14 deviating therefrom is conceivable at any time. The patient 15 may be pushed into the patient receiving area 14 by a patient support device 18 of the magnetic resonance device 10. To this end, the patient support device 18 includes a patient table 17 embodied movably within the patient receiving area 14.

The magnet unit 11 further includes a gradient coil unit 18 for the generation of magnetic field gradients, which are used for spatial encoding during imaging. The gradient coil unit 18 is controlled by a gradient control unit 19 of the magnetic resonance device 10. The magnet unit 11 further includes a radio-frequency antenna unit 20, which in the present exemplary embodiment is embodied as a body coil permanently integrated in the magnetic resonance device 10. The radio-frequency antenna unit 20 is designed for the excitation of atomic nuclei established in the basic magnetic field 13 generated by the basic magnet 12. The radio-frequency antenna unit 20 is controlled by a radio-frequency antenna control unit 21 of the magnetic resonance device 10 and irradiates radio-frequency pulse sequences into an examination chamber substantially formed by a patient receiving area 14 of the magnetic resonance device 10. The pulse sequences may in particular be designed to enable signal evolutions to be generated according to a magnetic resonance fingerprinting method. Furthermore, the radio-frequency antenna unit 20 is embodied to receive magnetic resonance signals.

To control the basic magnet 12, the gradient control unit 19 and the radio-frequency antenna control unit 21, the magnetic resonance device 10 includes a system control unit 22. The system control unit 22 controls the magnetic resonance device 10 centrally, such as, for example, for the performance of a predetermined imaging gradient echo sequence. The system control unit 22 also includes a unit for the evaluation of medical image data acquired during the magnetic resonance examination.

The system control unit 22 supports the performance of the method for the quantification of a volume element composition of an object under examination. To this end, the system control unit 22 includes a provisioning unit 27, an evaluation unit 26, and a data transmission unit 28. The magnetic resonance signals received by the radio-frequency antenna unit 20 may be forwarded to the provisioning unit 27. The spatial encoding of the magnetic resonance signals enables evaluation signal evolutions to be assigned to volume elements of the patient 15. These evaluation signal evolutions and database signal evolutions, which are, for example stored on a data storage unit, (e.g., a hard disk), of the provisioning unit 27, may be transferred via a data transmission unit 28 to the evaluation unit 26. The evaluation unit 26 is designed to determine weighting factors describing a composition of the volume elements on the basis of the transferred signal evolutions.

The magnetic resonance device 10 also includes a user interface 23 connected to the system control unit 22. Control information such as, for example, imaging parameters and reconstructed magnetic resonance images may be displayed on a display unit 24, (e.g., on at least one monitor), the user interface 23 for a medical operator. Similarly, the display unit 24 may also provide weighting factors determined according to the method.

The user interface 23 further includes an input unit 25 by which the information and/or parameters may be input by the medical operator during a measuring process. The input unit may also be used to define a possible total number of possible components and/or of possible postulated components and/or of possible potential components according to the method.

The system control unit 22 also includes a program storage unit and a processor unit by which software and/or computer programs stored in the program storage unit may be executed. In particular, this enables a computer program to be executed in order to carry out a method for the quantification of a volume element composition of an object under examination.

The magnetic resonance device 10 depicted in the present exemplary embodiment may include further components. In addition, the general mode of operation of a magnetic resonance device 10 is known to the person skilled in the art and so no detailed description of the general components will be given.

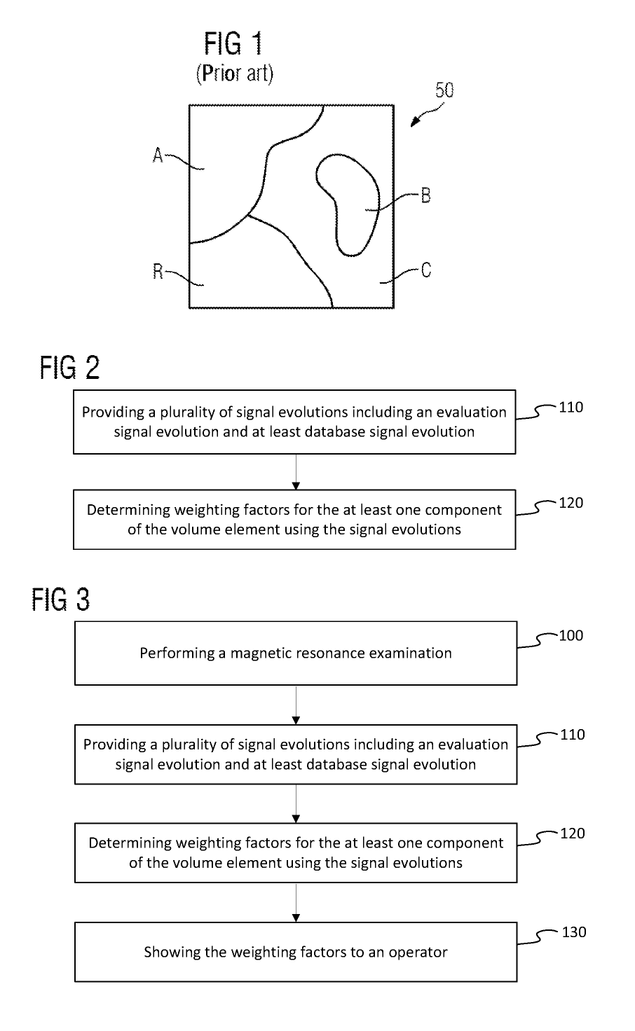

FIG. 1 is a schematic depiction of an exemplary volume element 50. For purposes of presentation, the volume element 50 is shown as two-dimensional. However, it is self-evident that it actually has a three-dimensional structure. The volume element 50 includes four different components A, B, C, R. Possible components of a human patient 15 are, for example, water, fat, gray brain matter, and white brain matter. The different components A, B, C, R interact in different ways with the electromagnetic waves, which are irradiated by the radio-frequency antenna unit 20 into the patient 15 and, in particular, into the volume element 50 comprised by the patient 15. The interaction is, inter alia, dependent upon the size and the molecular structure of the components A, B, C, R. The different interaction results in different contributions of the components to the magnetic resonance signal emitted by the volume element 50.

FIG. 2 depicts a method according to an embodiment. In act 110, a plurality of signal evolutions is provided including an evaluation signal evolution of the magnetic resonance signals and at least one database signal evolution. The provision may take place by the provisioning unit 27.

In act 120, weighting factors for the at least one component of the volume element are determined using the signal evolutions, wherein each signal evolution in each case includes a plurality of corresponding evaluation points to which a signal value is assigned in each case.

The signal evolutions normally include a sequence of signal values. FIG. 4 depicts signal values for database signal evolutions and FIG. 5 depicts signal values of an evaluation signal evolution. According to their position within the sequence, the signal values have different shape positions i, j, k, l.

In this case, a signal value corresponds to an amplitude of a pixel and/or voxel derived from a magnetic resonance signal received during a readout process of a pulse sequence. Put more simply, the sequence of the shape positions of the signal values may be equated to a, in particular temporal, sequence of pixels and/or voxels acquired by the pulse sequence, e.g., the pixel that was determined from magnetic resonance signals of a first readout process of the pulse sequence has the first shape position; the pixel that was determined from magnetic resonance signals of a second readout process of the pulse sequence has the second shape position, etc. Assignment to a specific volume element is enabled by the spatial encoding of the magnetic resonance signal, e.g., the volume element is depicted by a voxel and/or pixel of an MR image.

In this case, the evaluation signal evolution is a signal evolution assigned to a volume element that is to be evaluated with respect to its components with the aid of the method. FIG. 5 depicts signal values S_{Mi}, S_{Mj}, S_{Mk}, S_{Ml} of shape positions i, j, k, l of the evaluation signal evolution. The evaluation signal evolution may also include further signal values to which in each case another shape position is assigned. For example, the evaluation signal evolution may include 1000 signal values with shape positions 1, 2, . . . , 999, 1000. A number of signal values recorded in the context of a magnetic resonance fingerprinting method may be 1000 to 5000 items.

The top of FIG. 4 depicts signal values S_{Ai}, S_{Aj}, S_{Ak}, S_{Al} for shape positions i, j, k, l of the database signal evolution of component A. The middle of FIG. 4 depicts signal values S_{Bi}, S_{Bj}, S_{Bk}, S_{Bl} for the shape positions i, j, k, l of the database signal evolution of a component B. The bottom of FIG. 4 depicts signal values S_{Ci}, S_{Cj}, S_{Ck}, S_{Cl} of the shape positions i, j, k, l of the database signal evolution of a component C. The database signal evolutions also include many more signal values to which in each case another shape position is assigned. The database signal evolutions may, for example, be determined and/or simulated and/or calculated in a calibration measurement.

Advantageously, all signal evolutions are based on the same pulse sequence, e.g., the signal values of the evaluation signal evolution are determined on the basis of a measurement with which the same pulse sequence was used as with the experimental and/or theoretical determination of the database signal evolutions. In this case, each of the signal values of a signal evolution has its counterpart in one of the signal values of the other signal evolutions since the signal values for the other signal evolutions were determined with the same acquisition parameters. If a first signal value of a first signal evolution is determined on the basis of the same recording parameters and/or simulation parameters as a second signal value of a second signal evolution, the shape position of the first signal value and the shape position of the second signal value represent corresponding evaluation points. In the event of all signal evolutions being based on the same pulse sequence, identical shape positions of the signal evolutions also represent corresponding recording points. This case is assumed to be applicable in the following.

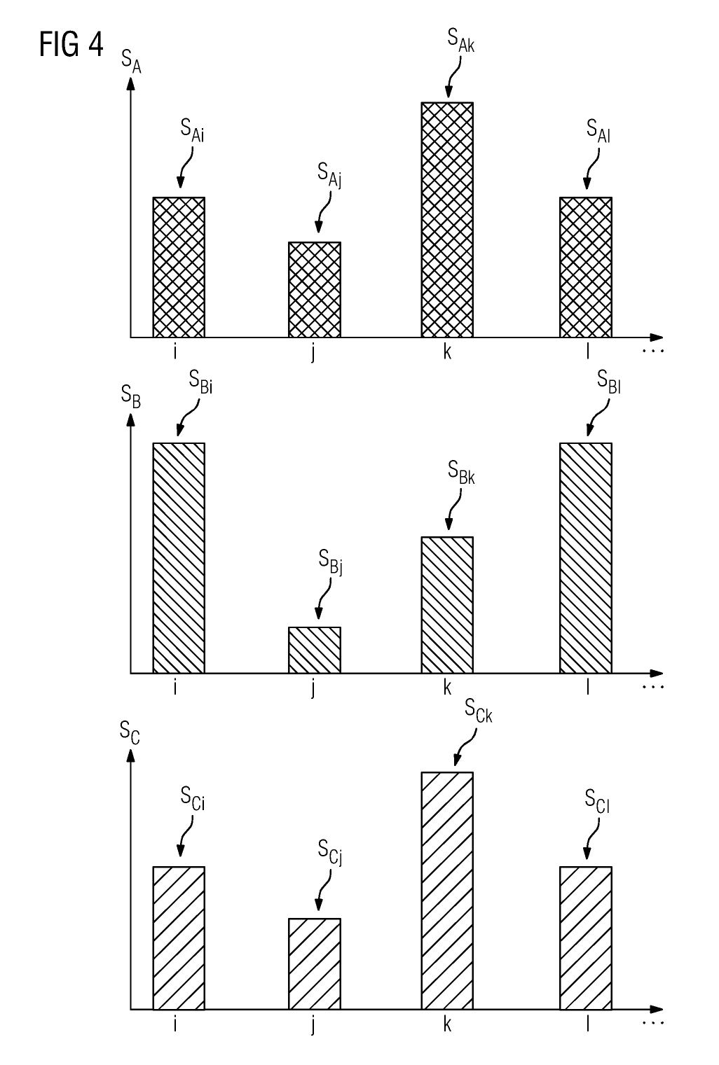

A priori, only the evaluation signal evolution, e.g., the signal values S_{Mi}, S_{Mj}, S_{Mk}, S_{Ml}, and at least one database signal evolution are known. In order to obtain an evaluation signal evolution of a volume element, a magnetic resonance examination is performed in an additional act 100, as depicted in FIG. 3, to record magnetic resonance signals.

For the determination of the weighting factors, it is at least possible to define a total number of possible components. For example, the total number may be defined as three. It is further possible for at least one postulated component to be defined, wherein each of the at least one postulated component is in each case assigned a postulated database signal evolution. For example, the components A, B and C may be postulated. For the four shape positions shown, i, j, k, l, this may be formulated mathematically as follows:

S_{Mi}=S_{AMi}+S_{BMi}+S_{CMi} (1)

S_{Mj}=S_{AMj}+S_{BMj}+S_{CMj} (2)

S_{Mk}=S_{AMk}+S_{BMk}+S_{CMk} (3)

S_{Ml}=S_{AMl}+S_{BMl}+S_{CMl} (4)

Consequently, S_{AMi} is a signal portion of the component A, S_{BMi} a signal portion of the component B and S_{CMi} a signal portion of the component C for the signal value S_{Mi} at the shape position i. The same applies to the further shape positions j, k and l.

The signal portion may be described as follows as the product of the weighting factors g_{A}, g_{B}, g_{C} of the component A, B, C and a signal value, which may in particular be comprised by a database shape assigned to the components A, B, C, at a corresponding evaluation point: S_{AMi}=g_{A}·S_{Ai}, S_{BMi}=g_{B}·S_{Bi}, S_{CMi}=g_{C}·S_{Ci}, S_{AMj}=g_{A}·S_{Aj}, etc. Hence, the equations (1), (2), (3), and (4) may be rewritten as:

S_{Mi}=g_{A}·S_{Ai}+g_{B}·S_{Bi}+g_{C}·S_{Ci} (5)

S_{Mj}=g_{A}·S_{Aj}+g_{B}·S_{Bj}+g_{C}·S_{Cj} (6)

S_{Mk}=g_{A}·S_{Ak}+g_{B}·S_{Bk}+g_{C}·S_{Ck} (7)

S_{Ml}=g_{A}·S_{Al}+g_{B}·S_{Bl}+g_{C}·S_{Cl} (8)

The equations (5), (6), (7), and (8) contain as unknown quantities the weighting factors g_{A}, g_{B}, g_{C}. To determine these, at least one system of equations including a plurality of equations may be compiled. Each of the plurality of equations relates in each case to one of the corresponding evaluation points, for example, equation (5) to the shape position i.

A system of equations of this kind may be solved easily using known solving methods. In particular, it has the advantage over possible other methods including, for example, matrix inversion acts that the method has high stability and/or that the result may be displayed to the operator of the magnetic resonance device in a short time. The provision of the weighting factors to an operator is shown in act 130 of FIG. 3.

Advantageously, the system of equations only includes the number of equations that is required for an unequivocal solution of the system of equations. In the case shown with three unknown quantities, this would be three independent equations; therefore, the number of equations of one of the system of equations is equal to the number of weighting factors to be determined g_{A}, g_{B}, g_{C}. In other words, the system of equations includes, for example, equations (5), (6), and (7) or the equations (5), (6), and (8) or the equations (5), (7), and (8) or the equations (6), (7), and (8).

Since signal evolutions may include significantly more than four signal values and therefore may have significantly more corresponding evaluation points, e.g., a plurality of different systems of equations is possible. For example, it is in particular possible to compile and solve a plurality of systems of equations, wherein each of the plurality of systems of equations relates to a different compilation of corresponding evaluation points. In this case, the compilation of evaluation points may be compiled from successive shape positions, for example shape points 1, 2, and 3, and/or randomly chosen shape positions, for example shape points 277, 564, 768.

In this way, depending upon the number of corresponding evaluation points available, it is possible to determine the weighting factors from the signal evolutions. The values determined for the weighting factors may be the same for each solved system of equations. In this case, there is a high probability that only the postulated components are actually present within the volume element under consideration.

However, it is also conceivable that a reliable limitation of the components to specific substances is not possible; therefore, that one portion of the magnetic resonance signal originates from different possible components. Therefore, it is possible to define a plurality of potential components for the determination of the weighting factors, wherein each of the plurality of potential components is in each case assigned a database signal evolution, wherein at least one resultant component is determined from the plurality of potential components. For example, with a defined total number of three possible components, two of the three components are defined as postulated components, (e.g., water and fat). For the third component, for example, two potential components are defined, for example, gray and white brain matter. In other words, the third component is limited to a group of possible substances. As described above, it is suggested that the weighting factors be calculated for the components assumed to be reliable, (e.g., water and fat), and in each case with the candidates, here gray and white brain matter, as a further component. A deviation, (e.g., the standard deviation), of the weighting factors may be used to determine the missing component as that with the lowest deviation and hence the greatest conformance. If in the example cited, the weighting factors for gray brain matter, for example, fluctuate much more greatly than those for white brain matter, there is a higher probability that the third component is white brain matter. It is possible to have as many candidates as possible, e.g., the number of potential components may in principle be as high as possible.

The deviation of the plurality of weighting factors following the determination of the at least one resultant component from among the plurality of potential components may be equal to zero. However, since the volume element may possibly also include further residual components, the deviation may also be different from zero. Therefore, it is suggested in a further aspect that at least one further piece of component information, (e.g., a n-tuple of physical values). To this end, a residual signal evolution is determined. This determination may be performed using equations, as was already illustrated by way of example in the equations (5), (6), (7), and (8). In this case, the residual signal evolution may be determined by the subtraction of signal portions determined from the signal values of the evaluation signal evolution, (e.g., in that the signals already determined), that is known, are deducted from a measured signal with a mean value of the weighting factors.

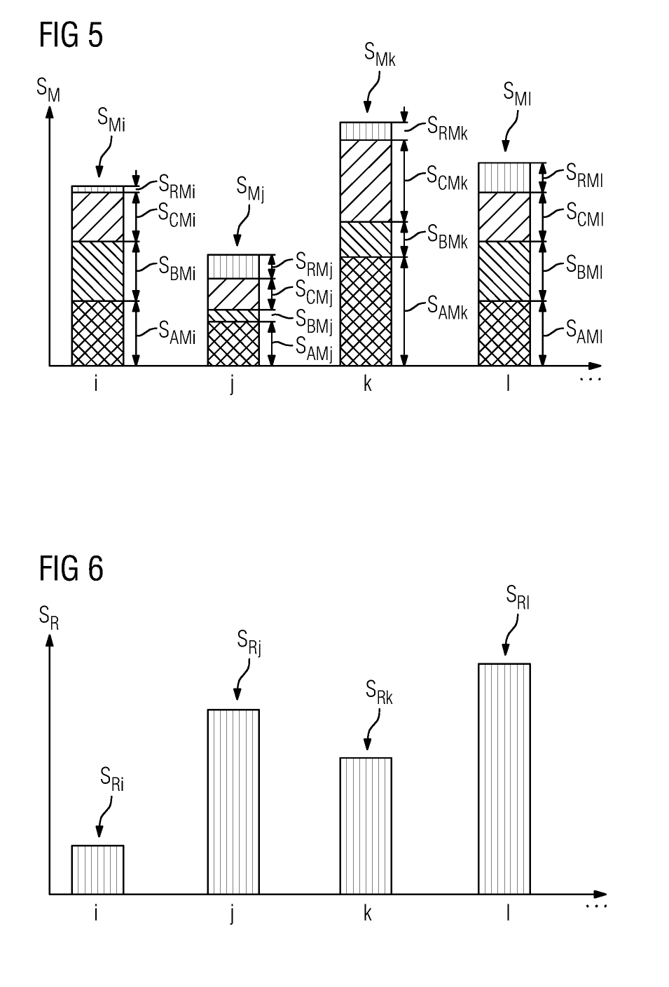

FIG. 6 depicts by way of example signal values S_{Ri}, S_{Rj}, S_{Rk}, S_{Rl} of a residual signal evolution. These signal values correspond to the difference of the signal values of the evaluation signal evolution S_{Mi}, S_{Mj}, S_{Mk}, S_{Ml} minus the portions of the components A, B, and C:

S_{Ri}=S_{Mi}−S_{AMi}−S_{BMi}−S_{CMi} (9)

S_{Rj}−S_{Mj}−S_{AMj}−S_{BMj}−S_{CMj} (10)

S_{Rk}=S_{Mk}−S_{AMk}−S_{BMk}−S_{CMk} (11)

S_{Rl}=S_{Ml}−S_{AMl}−S_{BMl}−S_{CMl} (12)

The residual signal evolution may then be processed by comparison with a plurality of database signal evolutions, for example, with the MRF method. For example, the residual signal evolution is assigned a database signal evolution stored in a database, which is in turn linked to at least one piece of component information.

To summarize, it is established that the present embodiments suggest a method for sub-pixel or sub-voxel quantification. This does not require the expected components to be completely defined in advance and it is possible for information to be provided on quantitative properties of possible further signal components of the pixel or voxel.

The method may, inter alia, be designed such that: the number of shape positions used to solve a system of equations is only equal to the number of components to be determined; the system of equations is solved frequently, but at least twice, wherein different sequential shape positions and/or randomly selected shape positions are used; and/or a deviation of the weighting factors is calculated.

In addition, in accordance with these aspects, it is possible for at least one expected component to be unknown, wherein, however, a selection of possible candidates may be selected and the at least one unknown component may be determined using a deviation of the weighting factors.

It is further, for example, possible to determine a residual signal portion from a mean value of the weighting factors and by the subtraction of a known signal portion, wherein for this residual signal portion, a conventional MRF evaluation is used to determine an n-tuple of quantitative values. This n-tuple may for example include a T1 time and/or a T2 time and/or an off-resonance of a substance.

The method may, in particular, be performed in that only postulated components, but no potential components, are defined and neither is any residual signal evolution determined. The method may furthermore also be carried out in that both postulated components and potential components are defined, but no residual signal evolution is determined. The method may furthermore, in particular, be carried out in that both postulated components and potential components are defined and a residual signal evolution is determined. The method may furthermore, in particular, be carried out in that only postulated components, but no potential components, are defined and a residual signal evolution is determined.

Finally, reference is made once again to the fact that the methods and devices described in detail above are only exemplary embodiments that may be modified by the person skilled in the art in a wide variety of ways without departing from the scope of the invention. Furthermore, the use of indefinite article “a” or “an” does not preclude the possibility of the features in question being present on a multiple basis. Similarly, the term “unit” does not preclude the possibility components in question of this including a plurality of interacting partial components that may also be spatially distributed.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for the quantification of a volume element composition of an object under examination using magnetic resonance signals generated by an interaction of electromagnetic waves with at least one component of the volume element composition, the method comprising:
providing a plurality of signal evolutions comprising an evaluation signal evolution of the magnetic resonance signals and at least one database signal evolution; and
determining weighting factors for the at least one component of the volume element composition using the plurality of signal evolutions,
wherein each signal evolution of the plurality of signal evolutions comprises a plurality of corresponding evaluation points, wherein each evaluation point is assigned a signal value.

2. The method of claim 1, wherein the volume element is depicted by a voxel, a pixel, or a voxel and pixel of a magnetic resonance image.

3. The method of claim 1, further comprising:
recording magnetic resonance signals, wherein the recorded magnetic resonance signals are used to determine the evaluation signal evolution.

4. The method of claim 1, further comprising:
providing the determined weighting factors to an operator.

5. The method of claim 1, wherein the plurality of signal evolutions are generated according to a magnetic resonance fingerprinting method.

6. The method of claim 1, wherein at least one total number of possible components is defined for the determining of the weighting factors.

7. The method of claim 1, further comprising:
defining at least one postulated component for the determining of the weighting factors; and
assigning a database signal evolution to each postulated component of the at least one postulated component.

8. The method of claim 1, further comprising:
defining a plurality of potential components for the determining of the weighting factors;
assigning a database signal evolution to each potential component of the plurality of potential components; and
determining at least one resultant component from the plurality of potential components.

9. The method as claimed in claim 8, wherein a plurality of weighting factors is calculated for each potential component of the plurality of potential components, and
wherein the at least one resultant component has a minimum deviation of the plurality of weighting factors.

10. The method of claim 1, further comprising:
determining a residual signal evolution; and
determining, using the residual signal evolution, at least one piece of component information by comparison with plurality of database signal evolutions.

11. The method of claim 10, wherein the residual signal evolution is determined by the subtraction of signal portions from the signal values of the evaluation signal evolution.

12. The method of claim 1, wherein the weighting factors are determined using a mean value of provisional weighting factors.

13. The method of claim 1, wherein at least one system of equations is created and solved for the determination of the weighting factors,
wherein each system of equations of the at least one system of equations comprises a plurality of equations.

14. The method of claim 13, wherein each equation of the plurality of equations relates to one of the corresponding evaluation points.

15. The method of claim 14, wherein a plurality of systems of equations are created and solved, and
wherein each system of equations of the plurality of systems of equations relates to a different compilation of corresponding evaluation points.

16. The method of claim 15, wherein the compilation of evaluation points is compiled from successive evaluation points, randomly chosen evaluation points, or both the successive evaluation points and the randomly chosen evaluation points.

17. The method of claim 13, wherein a maximum number of equations comprised by the at least one system of equations is only a number of equations required for an unequivocal solution of the system of equations.

18. The method of claim 13, wherein a number of equations of a system of equations of the at least one system of equations is equal to a number of weighting factors to be determined.

19. A magnetic resonance device comprising:
a provisioning unit for providing a plurality of signal evolutions comprising an evaluation signal evolution and at least one database signal evolution; and
an evaluation unit for the evaluation of the plurality of signal evolutions, wherein the evaluation unit is configured to determine weighting factors for at least one component of a volume element composition of an object under examination using the plurality of signal evolutions,
wherein each signal evolution of the plurality of signal evolutions comprises a plurality of corresponding evaluation points, wherein each evaluation point is assigned a signal value.

20. A computer program product, which comprises a program and configured to be loaded directly into a memory of a programmable system control unit of a magnetic resonance device, wherein when the program is executed in the system control unit of the magnetic resonance device, the computer program product is configured to:
provide a plurality of signal evolutions comprising an evaluation signal evolution of the magnetic resonance signals and at least one database signal evolution; and
determine weighting factors for the at least one component of the volume element composition using the plurality of signal evolutions,
wherein each signal evolution of the plurality of signal evolutions comprises a plurality of corresponding evaluation points, wherein each evaluation point is assigned a signal value.
